(19) United States
(12) Patent Application Publication
(10) Pub. No.: US 2017/0309490 A1
(43) Pub. Date: Oct. 26, 2017

(54) METHOD OF MANUFACTURING SEMICONDUCTOR DEVICE

(71) Applicant: HITACHI KOKUSAI ELECTRIC INC., Tokyo (JP)

(72) Inventor: Arito OGAWA, Toyama (JP)

(73) Assignee: HITACHI KOKUSAI ELECTRIC INC., Tokyo (JP)

(21) Appl. No.: 15/513,415

(22) PCT Filed: Sep. 24, 2014
(86) PCT No.: PCT/JP2014/075232

§ 371 Date: Mar. 22, 2017

(51) Int. Cl. H01L 21/285; C23C 16/455; C23C 16/06; C23C 16/34

(52) U.S. Cl. CPC H01L 21/28556; H01L 21/28568; C23C 16/45527; C23C 16/06; C23C 16/34; C23C 16/45525

(57) ABSTRACT

A method of manufacturing a semiconductor device includes: forming an amorphous metal film on a substrate by time-divisionally conducting a cycle a predetermined number of times, the cycle including: (a) simultaneously supplying a metal-containing gas and a first reducing gas to the substrate to form a first amorphous metal layer on the substrate, and (b) forming a second amorphous metal layer on the first amorphous metal layer by time-divisionally supplying, a predetermined number of times, the metal-containing gas and a second reducing gas to the substrate on which the first amorphous metal layer is formed; and forming a crystallized metal layer on the substrate by simultaneously supplying the metal-containing gas and the first reducing gas to the substrate on which the amorphous metal film is formed.

### TECHNICAL FIELD

The present invention relates to a method of manufacturing a semiconductor device in which a thin film is formed on a substrate.

### BACKGROUND ART

In recent years, with an increase in circuit integration and improvement in performance, it is demanded to form a metal film in an extra fine groove having a narrower than conventional opening portion. In addition, a low resistivity is demanded of a metal film. Applications of such a metal film include, for example, applications to control gate of a flash memory, to a gate electrode of a DRAM (Dynamic Random Access Memory), to wiring between electrodes, and the like.

### SUMMARY

When embedding a metal film in an opening portion, use of a crystallized film increases surface roughness (also referred to simply as roughness) to generate a void in some cases. However, when using a non-crystalline (amorphous) film in order to reduce surface roughness, a temperature at the time of film formation should be low, resulting in making a resistivity of an obtained metal film high.

A main object of the present invention is to solve the above problem and provide a technique that enables formation of a high-quality film with reduced roughness and a low resistivity.

According to one embodiment of the present invention, there is provided a method of manufacturing a semiconductor device including: forming an amorphous metal film on a substrate by time-divisionally conducting a cycle a predetermined number of times, the cycle including: (a) simultaneously supplying a metal-containing gas and a first reducing gas to the substrate to form a first amorphous metal layer on the substrate, and (b) forming a second amorphous metal layer on the first amorphous metal layer by time-divisionally supplying, a predetermined number of times, the metal-containing gas and a second reducing gas to the substrate on which the first amorphous metal layer is formed; and forming a crystallized metal layer on the substrate by simultaneously supplying the metal-containing gas and the first reducing gas to the substrate on which the amorphous metal film is formed.

The present invention provides a technique that enables formation of a high-quality film with reduced roughness and a low resistivity.

### BRIEF DESCRIPTION OF DRAWINGS

FIG. 1 is a schematic structural view illustrating a processing furnace of a substrate processing apparatus suitably used in a first embodiment of the present invention, and is a view showing a part of the processing furnace as a vertical sectional view.

FIG. 2 is a sectional view taken along a line A-A in FIG. 1.

FIG. 3 is a block diagram showing a configuration of a controller that the substrate processing apparatus shown in FIG. 1 has.

FIG. 4 is a block diagram showing an example of a stack structure to which a film formed in the first embodiment of the present invention is applicable.

FIG. 5 is a diagram showing a sequence at the time of formation of a bulk layer in the first embodiment of the present invention.

FIG. 6 is a diagram showing a sequence at the time of formation of a seed layer in the first embodiment of the present invention.

### DETAILED DESCRIPTION

As a metal film for use in an electrode used in such a memory as a flash memory, a Dynamic Random Access Memory (DRAM) or the like, or in wiring between electrodes, or the like, a tungsten (W) film is used, for example. Methods of forming such a film include a method of simultaneously supplying a plurality of processing gases to a substrate (successive supply) to use a reaction of the plurality of processing gases in a gas phase or on a surface of the substrate, thereby forming a film on the substrate, a method of time-divisionally (asynchronously, intermittently, pulsively) supplying a plurality of processing gases to a substrate to form a film on the substrate, and the like. When embedding a metal film in such an extra fine groove having a narrow opening portion as a plug or the like, the latter method of time-divisionally supplying a plurality of processing gases is effective, the method enabling more excellent uniformity in a film thickness to be obtained. However, since in such a case, the obtained metal film has an increased resistivity, the former method is more often employed of simultaneously supplying a plurality of processing gases for forming a W film.

In addition, in a case of embedding a metal film in such an extra fine groove having a narrow opening portion as a plug or the like, since high roughness prevents suitable embedding to possibly generate a void, a metal film at the time of embedding is desirably in an amorphous state. However, since a W film has a low crystallization temperature, with a method of simultaneously supplying a plurality of processing gases, crystallization occurs at approximately 200 to 250° C. Although it is possible, when forming a W film, to add impurities to make the film amorphous, thereby forming a low roughness film, since a temperature required for crystallizing an amorphous W film formed with impurities added is 500° C. or more, usable steps are limited and a resistivity of an obtained metal film is increased. Accordingly, required as a W film to be formed in an extra fine groove having a narrow opening portion is a W film which is formed by low temperature processing and is crystallized with low roughness and a low resistivity.

The inventors conducted intensive studies to find that when a crystallized W layer is formed on an amorphous W film, the crystallized W layer affects the amorphous W film to crystallize the amorphous W film, resulting in forming a crystallized W film on a substrate (reversed solid phase reaction). A temperature required for forming a crystallized W layer is as low as 250° C. or less and preferably 200° C. or less. In addition, it has been found that even when a plurality of processing gases is simultaneously supplied to a substrate to form a film at a temperature of approximately 200° C., an amorphous W layer (A) can be formed to have up to a fixed film thickness (a). Further, it has been found that by time-divisionally supplying a W-containing gas and a reducing gas including impurities to a substrate to form a film, even at low temperature of 250° C. or less and preferably 200° C. or less, a low roughness amorphous W layer (B) can be formed. Then, it has been found that by forming the amorphous W layer (B) on the amorphous W layer (A) and further forming the amorphous W layer (A) to overlap with the layers, an amorphous W film having a film thickness larger than the fixed film thickness (a) can be formed. Specifically, it has been found that by sandwiching the amorphous W layer (B) between the amorphous W layers (A) (laminating the amorphous W layers (A) and the amorphous W layer (B)), an amorphous W film having a desired film thickness can be formed.

Accordingly, combining the amorphous W layer (A) and the amorphous W layer (B) to form an amorphous W film having a desired film thickness and form a crystallized W layer thereon enables formation of a crystallized W film in an extra fine groove having a narrow opening portion by low temperature processing conducted at 200° C. or less, the W film having low roughness and a low resistivity. Detailed description will be made in the following.

### First Embodiment of the Present Invention

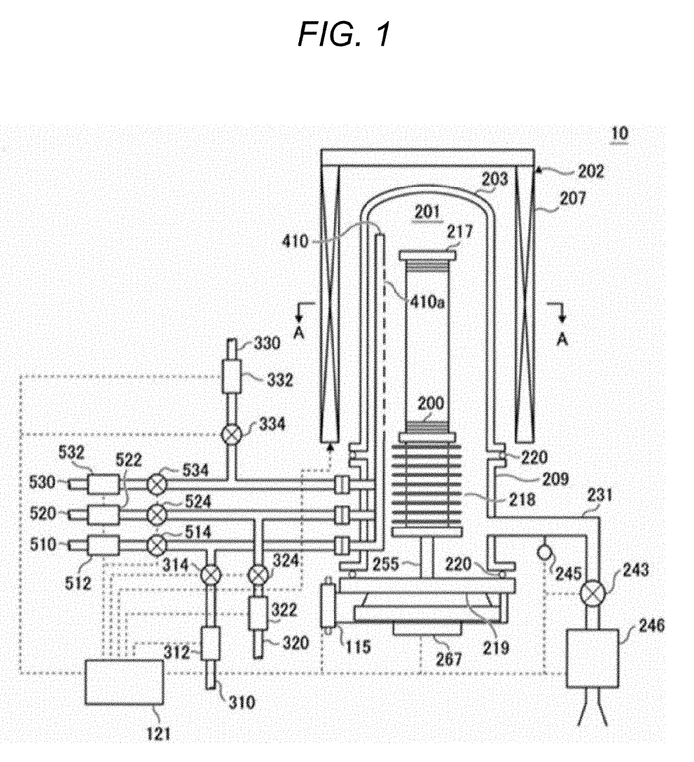

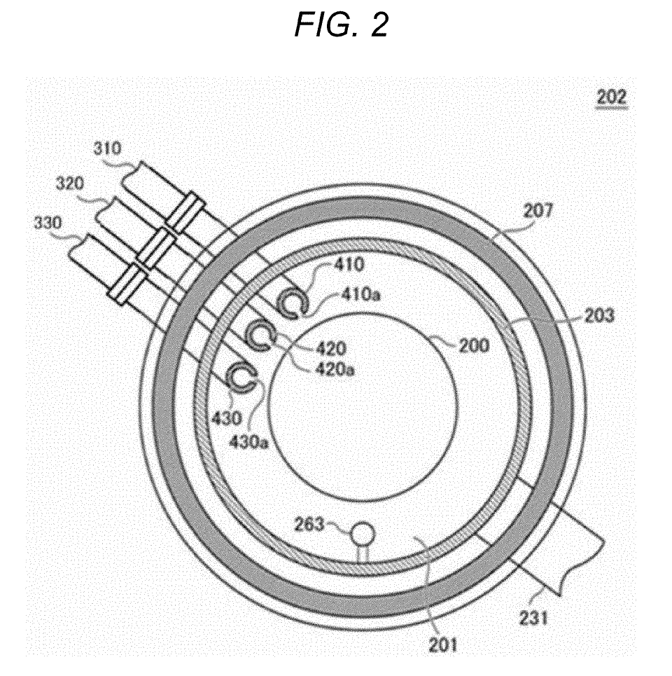

In the following, a first embodiment of the present invention will be described with reference to FIG. 1 and FIG. 2. A substrate processing apparatus 10 is configured as one example of an apparatus for use in a substrate processing step which is one step of semiconductor device manufacturing steps.

(1) Configuration of Processing Furnace

A processing furnace 202 is provided with a heater 207 as heating means (a heating mechanism, a heating system). The heater 207 is formed to have a cylindrical shape with an upper portion opened.

On an inner side of the heater 207, a reaction tube 203 is disposed which configures a reaction container (processing container) so as to be concentrical with the heater 207. The reaction tube 203 is made of a heat-resistant material or the like (e.g. quartz (SiO₂) or silicon carbide (SiC)) and is formed to be cylindrical with an upper end thereof blocked and a lower end thereof opened.

To a lower end of the reaction tube 203, a manifold 209 made of a metal material such as stainless or the like is attached. The manifold 209 is formed to be tubular with a lower end opening thereof air tightly blocked by a seal cap 219 made of a metal material such as stainless or the like as a cap body. Between the reaction tube 203 and the manifold 209, and between the manifold 209 and the seal cap 219, O-rings 220 are provided, respectively, as a sealing member. The processing container is configured mainly with the reaction tube 203, the manifold 209 and the seal cap 219, within which processing container, a processing chamber 201 is formed. The processing chamber 201 is configured such that wafers 200 as a substrate can be housed in a horizontal posture so as to be aligned vertically in a multi-stage manner by a boat 217 which will be described later.

On a side of the seal cap 219 opposite to the processing chamber 201, a rotation mechanism 267 is disposed which rotates the boat 217. A rotation shaft 255 of the rotation mechanism 267 extends through the seal cap 219 so as to be connected to the boat 217. The rotation mechanism 267 is configured to rotate the wafer 200 by the rotation of the boat 217. The seal cap 219 is configured to move up and down in the vertical direction by a boat elevator 115 vertically disposed as an up-and-down mechanism outside the reaction tube 203. The boat elevator 115 is configured to carry the boat 217 inside and outside the processing chamber 201 by moving the seal cap 219 up and down. Specifically, the boat elevator 115 is configured as a transfer device (transfer mechanism) which transfers the boat 217, i.e., the wafer 200, to the inside and outside of the processing chamber 201.

The boat 217 as a substrate holder is configured so as to support a plurality of, for example, 25 to 200 wafers 200 in a horizontal posture such that the wafers are centered and aligned in the vertical direction in a multi-stage manner, i.e., such that the wafers are disposed with a space from each other. The boat 217 is made of a heat-resistant material or the like (e.g., quartz or SiC). At a bottom portion of the boat 217, heat insulation plates 218 each made of a heat-resistant material or the like (e.g., quartz or SiC) are supported in a horizontal posture and in a multi-stage manner. This configuration makes difficult heat conduction from the heater 207 to the side of the seal cap 219. However, the present embodiment is not limited to the above mode. For example, without providing the heat insulation plates 218 at the bottom portion of the boat 217, a heat insulation tube may be provided which is configured as a tubular member made of a heat-resistant material such as quartz, SiC or the like. The heater 207 is capable of heating the wafer 200 housed in the processing chamber 201 to a predetermined temperature.

In the processing chamber 201, nozzles 410, 420 and 430 are provided so as to extend through a side wall of the manifold 209. To the nozzles 410, 420 and 430, gas supply pipes 310, 320, and 330 as a gas supply line are connected, respectively. Thus, the processing furnace 202 is provided with the three nozzles 410, 420 and 430 and the three gas supply pipes 310, 320, and 330 and is configured to supply a plurality of kinds, three kinds here, of gases (processing gases) into the processing chamber 201 by dedicated lines, respectively.

The gas supply pipes 310, 320, and 330 are provided, sequentially from an upstream side, with mass flow controllers (MFC) 312, 322, and 332 as a flow rate controller (flow rate control unit), and provided with valves 314, 324, and 334 as a switching valve. To front end portions of the gas supply pipes 310, 320, and 330, the nozzles 410, 420 and 430 are coupled (connected), respectively. The nozzles 410, 420 and 430 are configured to be L-shaped long nozzles, and horizontal portions thereof are provided so as to extend through the side wall of the manifold 209. Vertical portions of the nozzles 410, 420 and 430 are provided so as to rise upwardly (upward in a direction where the wafers 200 are piled) along an inner wall of the reaction tube 203, in an annular space formed between the inner wall of the reaction tube 203 and the wafer 200 (i.e. so as to rise from one end side of a wafer disposition region toward the other side of the same). Specifically, the nozzles 410, 420 and 430 are provided on a side of the wafer disposition region in which the wafers 200 are disposed, in a region horizontally surrounding the wafer disposition region and along the wafer disposition region.

On side surfaces of the nozzles 410, 420 and 430, gas supply holes 410a, 420a, and 430a for supplying (jetting) a gas are provided, respectively. The gas supply holes 410a, 420a, and 430a are each opened so as to face the center of the reaction tube 203. From a bottom portion of the reaction tube 203 to a top portion thereof, a plurality of the gas supply holes 410a, 420a, and 430a is provided to each have the same area of an opening which is provided at the same opening pitch.

Thus, in a gas supply method in the present embodiment, a gas is transferred via the nozzles 410, 420 and 430 arranged in a longitudinal space having an annular shape which is defined by the inner wall of the reaction tube 203 and end portions of the plurality of wafers 200 piled, i.e., in a tubular space, to jet a gas into the reaction tube 203 first in proximity to the wafers 200 from the gas supply holes 410a, 420a, and 430a opened in the nozzles 410, 420 and 430, respectively, in which a main flow of a gas in the reaction tube 203 is in a direction parallel to a surface of the wafer 200, i.e., in a horizontal direction. Such a configuration enables uniform supply of a gas to each wafer 200, thereby producing an effect of uniforming a film thickness of a thin film formed on each wafer 200. Although a gas having flowed on the surface of each wafer 200, i.e., a gas remaining after reaction (residual gas), flows toward an exhaust port, i.e., to a direction of an exhaust pipe 231 which will be described later, a flow direction of the residual gas is appropriately specified by a position of the exhaust port and is not limited to the vertical direction.

In addition, to the gas supply pipes 310, 320, and 330, carrier gas supply pipes 510, 520, and 530 for supplying a carrier gas are connected. At the carrier gas supply pipes 510, 520, and 530, MFCs 512, 522, and 532, and valves 514, 524, and 534 are provided, respectively.

As one example of the above configuration, from the gas supply pipe 310, a material gas containing a metallic element (metal-containing material, metal-containing gas, metal material) is supplied as a processing gas into the processing chamber 201 via the MFC 312, the valve 314, and the nozzle 410. As the material gas, for example, a tungsten hexafluoride (WF₆) gas as a W-containing material gas is used which contains tungsten (W) as a metallic element. The WF₆ gas functions as a W source in a substrate processing step which will be described later.

From the gas supply pipe 320, a second reducing gas having a function of reducing a material gas is supplied as a processing gas into the processing chamber 201 via the MFC 322, the valve 324, and the nozzle 420. As the second reducing gas, a hydrogen-containing gas which contains hydrogen (H), for example, hydrogen (H₂) is used. The H₂ gas functions as an H source in the substrate processing step which will be described later.

From the gas supply pipe 330, a first reducing gas having a function of reducing a material gas is supplied as a processing gas into the processing chamber 201 via the MFC 332, the valve 334, and the nozzle 430. As the first reducing gas, a boron-containing gas which contains boron (B), for example, diborane (B₂H₆) is used. The B₂H₆ gas functions as a B source in the substrate processing step which will be described later.

From the carrier gas supply pipes 510, 520, and 530, for example, a nitrogen (N₂) gas is supplied as an inert gas into the processing chamber 201 via the MFCs 512, 522, and 532, and the valves 514, 524, and 534, the nozzles 410, 420 and 430, respectively.

Here, in the present specification, a processing gas, a material gas, and a reducing gas represent a gas obtained by vaporizing or subliming a material or a reducing agent in a gas state, for example, a material or a reducing agent in a liquid state or a solid state under room temperature and normal pressure, or represent a material or a reducing agent in a gas state under room temperature and normal pressure, and the like. In the present specification, the term “material” in some cases represents “a liquid material in a liquid state”, “solid material in a solid state”, “a material gas in a gas state”, or a combination thereof. In the present specification, the term “reducing agent” in some cases represents “a liquid reducing agent in a liquid state”, “a solid reducing agent in a solid state”, “a reducing gas in a gas state”, or a combination thereof. When a liquid material or the like in a liquid state under room temperature and normal pressure or a solid material or the like in a solid state under room temperature and normal pressure is used, a liquid material or the like, or a solid material or the like will be vaporized or sublimed by such a system as a vaporizer, a bubbler or a sublimation unit to supply a resultant material as a material gas or a reducing gas.

When causing such a processing gas to flow as described above from the gas supply pipes 310, 320, and 330, a processing gas supply system is configured mainly with the gas supply pipes 310, 320, and 330, the MFCs 312, 322, and 332, and the valves 314, 324, and 334. The nozzles 410, 420, and 430 can be considered to be included in the processing gas supply system. The processing gas supply system can be simply referred to as a gas supply system as well.

When causing such a material gas to flow as described above from the gas supply pipe 310, a material gas supply system is configured mainly with the gas supply pipe 310, the MFC 312, and the valve 314. The nozzle 410 can be considered to be included in the material gas supply system. The material gas supply system can be referred to also as a material supply system.

When causing a W-containing gas to flow as a material gas from the gas supply pipe 310, a W-containing gas supply system is configured mainly with the gas supply pipe 310, the MFC 312, and the valve 314. The nozzle 410 can be considered to be included in the W-containing gas supply system. The W-containing gas supply system can be referred to as a W-containing material supply system, or simply referred to as a W material supply system as well. When causing a WF₆ gas to flow from the gas supply pipe 310, the W-containing gas supply system can be referred to also as a WF₆ gas supply system. The WF₆ gas supply system can be referred to also as a WF₆ supply system.

When causing such a reducing gas as described above to flow from the gas supply pipes 320 and 330, a reducing gas supply system is configured mainly with the gas supply pipes 320 and 330, the MFCs 322 and 332, and the valves 324 and 334. The nozzles 420 and 430 can be considered to be included in the reducing gas supply system. The reducing gas supply system can be referred to also as a reducing agent supply system.

When causing an H-containing gas as a reducing gas to flow from the gas supply pipe 320, an H-containing gas supply system is configured mainly with the gas supply pipe 320, the MFC 322, and the valve 324. The nozzle 420 can be considered to be included in the H-containing gas supply system. When causing an H₂ gas to flow from the gas supply pipe 320, the H-containing gas supply system can be referred to also as an H₂ gas supply system. The H₂ gas supply system can be referred to also as an H₂ supply system.

When causing a B-containing gas as a reducing gas to flow from the gas supply pipe 330, a B-containing gas supply system is configured mainly with the gas supply pipe 330, the MFC 332, and the valve 334. The nozzle 430 can be considered to be included in the B-containing gas supply system. The B-containing gas supply system can be also referred to as a B-containing reducing gas supply system, and can be referred to also as a B-containing reducing agent supply system. When causing a B₂H₆ gas to flow from the gas supply pipe 330, the B-containing gas supply system can be referred to also as a B₂H₆ gas supply system. The B₂H₆ gas supply system can be referred to also as a B₂H₆ supply system.

In addition, a carrier gas supply system is configured mainly with the carrier gas supply pipes 510, 520, and 530, the MFCs 512, 522, and 532, and the valves 514, 524, and 534. When causing a flow of an inert gas as a carrier gas, the carrier gas supply system can be referred to also as an inert gas supply system. Since the inert gas functions also as a purge gas, the inert gas supply system can be referred to also as a purge gas supply system.

In the manifold 209, an exhaust pipe 231 is provided which discharges an atmosphere in the processing chamber 201. The exhaust pipe 231, similarly to the nozzles 410, 420 and 430, is provided so as to extend through the side wall of the manifold 209. The exhaust pipe 231, as shown in FIG. 2, is provided at a position opposed to the nozzles 410, 420 and 430 with the wafer 200 provided therebetween in a plane view. In this configuration, a gas supplied from the gas supply holes 410a, 420a, and 430a to the proximity of the wafer 200 in the processing chamber 201 flows in a horizontal direction, i.e. toward a direction parallel to the surface of the wafer 200 and then flows downward to be discharged from the exhaust pipe 231. A main flow of a gas in the processing chamber 201 will be a flow toward the horizontal direction as described above.

Connected to the exhaust pipe 231, sequentially from the upstream side, are a pressure sensor 245, as a pressure detector (pressure detection unit) which detects a pressure in the processing chamber 201, an APC (Auto Pressure Controller) valve 243 as a pressure controller (pressure control unit) which controls a pressure in the processing chamber 201, and a vacuum pump 246 as an evacuation device. The APC valve 243 is configured to be capable of evacuating and stopping evacuating the processing chamber 201 by opening or closing the valve, with the vacuum pump 246 in operation, and to be further capable of adjusting a pressure in the processing chamber 201 by regulating a valve opening degree on the basis of pressure information detected by the pressure sensor 245, with the vacuum pump 246 in operation. The APC valve 243 configures a part of an exhaust flow channel of an exhaust system and functions not only as a pressure adjustment unit but also as an exhaust flow channel opening and closing unit capable of blocking the exhaust flow channel of the exhaust system or further air tightly closing the same, i.e. also as an exhaust valve. In addition, to the exhaust pipe 231, a trap device which captures a reaction by-product, an unreacted material gas or the like in an exhaust gas, or a detoxifying device which detoxifies a corrosive component, a toxic component or the like contained in an exhaust gas may be connected in some cases. An exhaust system, i.e. an exhaust line, is configured mainly with the exhaust pipe 231, the APC valve 243, and the pressure sensor 245. Note that the vacuum pump 246 can be considered to be included in the exhaust system. Further, a trap device or a detoxifying device can be considered to be included may be included in the exhaust system.

In the reaction tube 203, a temperature sensor 263 as a temperature detector is disposed so that adjustment of an amount of energization to the heater 207 on the basis of temperature information detected by the temperature sensor 263 enables the temperature of the processing chamber 201 to obtain a desired temperature distribution. Similarly to the nozzles 410, 420, and 430, the temperature sensor 263 is configured to be L-shaped and provided along the inner wall of the reaction tube 203.

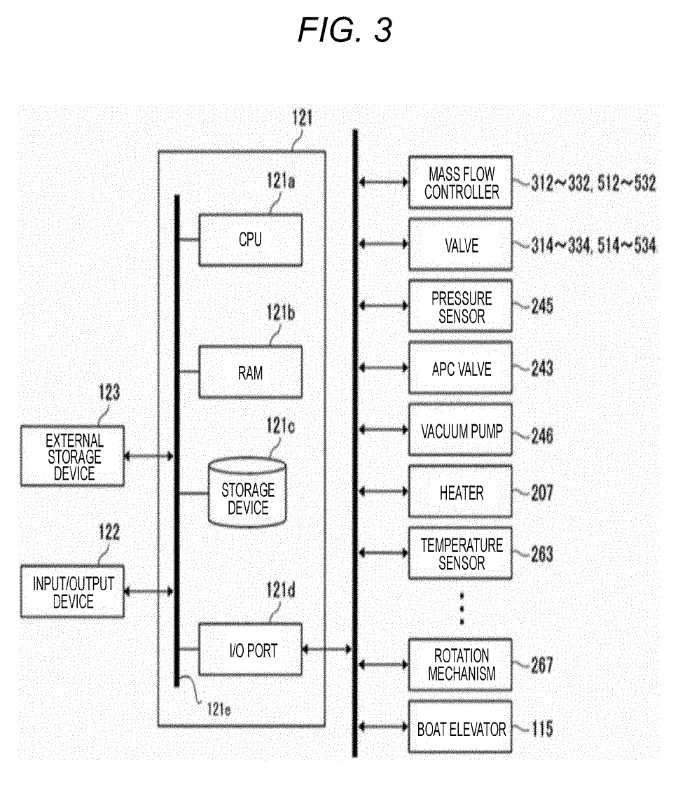

As shown in FIG. 3, a controller 121 as a control unit (control means) is configured as a computer including a CPU (Central Processing Unit) 121a, a RAM (Random Access Memory) 121b, a storage device 121c, and an I/O port 121d. The RAM 121b, the storage device 121c, and the I/O port 121d are configured to be capable of exchanging data with the CPU 121a via an internal bus 121e. To the controller 121, an input/output device 122 configured as a touch panel or the like is connected.

The storage device 121c is configured with a flash memory, an HDD (Hard Disk Drive) or the like. In the storage device 121c, a control program which controls operation of a substrate processing apparatus, a process recipe which recites a procedure, a condition and the like for the substrate processing which will be described later, and the like are stored so as to be readable. The process recipe is a combination of the respective procedures in the substrate processing step to be described later, the combination being made so as to be executed by the controller 121 to obtain a specific result, and the process recipe functions as a program. In the following, this process recipe, a control program and the like will be also generically referred to simply as a program. The term, program, in the present specification may include a process recipe singly, may include a control program singly, or may include both. In addition, the RAM 121b is configured as a memory region (work area) in which a program, data and the like read by the CPU 121a are temporarily held.

The I/O port 121d is connected to the above-described MFCs 312, 322, 332, 512, 522, and 532, the valves 314, 324, 334, 514, 524, and 534, the APC valve 243, the pressure sensor 245, the vacuum pump 246, the heater 207, the temperature sensor 263, the rotation mechanism 267, the boat elevator 115 and the like.

The CPU 121a is configured to read a control program from the storage device 121c and execute the same, as well as reading a process recipe from the storage device 121c according to input of an operation command from the input/output device 122 or the like. The CPU 121a is configured to, according to a read process recipe, control flow rate adjustment operation for various gases conducted by the MFCs 312, 322, 332, 512, 522, and 532, opening and closing operation of the valves 314, 324, 334, 514, 524, and 534, opening and closing operation of the APC valve 243, pressure adjustment operation by the APC valve 243 on the basis of the pressure sensor 245, temperature adjustment operation of the heater 207 on the basis of the temperature sensor 263, activation and stop of the vacuum pump 246, rotation and rotation speed regulation operation of the boat 217 by the rotation mechanism 267, up-and-down operation of the boat 217 by the boat elevator 115, and the like.

The controller 121 can be configured to be a general-purpose computer, not limited to a dedicated computer. For example, with an external storage device 123 prepared (e.g. a magnetic tape, a magnetic disk such as a flexible disk, a hard disk or the like, an optical disc such as a CD, a DVD or the like, a magneto-optical disk such as a MO or the like, and a semiconductor memory such as a USB memory, a memory card or the like) which stores the above program, the controller 121 of the present embodiment can be configured by installing the program in a general-purpose computer by using the external storage device 123, or the like. Means for supplying a computer with a program is not limited to means which supplies a program via the external storage device 123. For example, a program can be supplied using communication means such as the Internet, a dedicated line or the like, not via the external storage device 123. The storage device 121c and the external storage device 123 are configured as a computer-readable recording medium. In the following, these means will be generically referred simply as a recording medium as well. In the present specification, the term, recording medium, may represent the storage device 121c singly, may represent the external storage device 123 singly, or may represent both.

(2) Substrate Processing Step

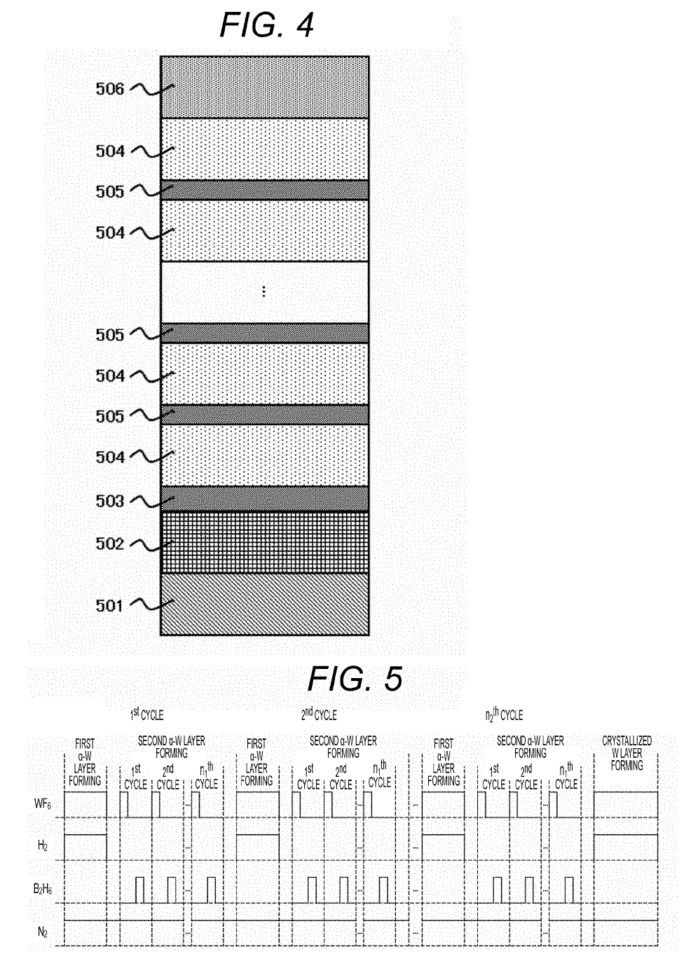

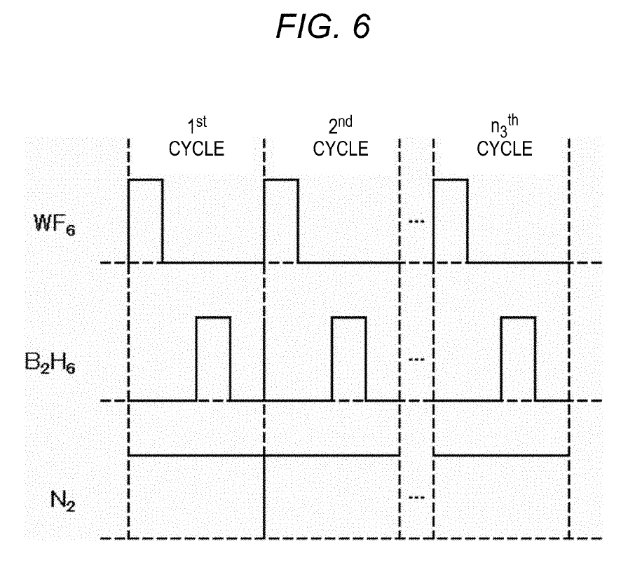

Description will be made of one example of a step of forming a metal film configuring, for example, a gate electrode, on a substrate as one step of a semiconductor device manufacturing step with reference to FIG. 4, FIG. 5, and FIG. 6. The step of forming a metal film is executed using the processing furnace 202 of the above-described substrate processing apparatus 10. In the following description, operation of each unit configuring the substrate processing apparatus 10 is controlled by the controller 121.

FIG. 4 shows an example of a stack structure to which the present embodiment is applied. FIG. 4 shows an example of forming a crystallized tungsten film (a W film) by forming, for example, a titanium nitride film (a TiN film) 502, as a barrier metal film, on a silicon oxide film (a SiO₂ film) 501, forming, for example, a tungsten film (a W film) 503, as a seed layer, on the TiN film 502, an amorphous tungsten film (an amorphous W film, an α-W film) obtained by alternately laminating, for example, amorphous tungsten layers (an amorphous W layer, an α-W layer) 504 and 505, as a bulk layer, on the W film 503, and further forming a crystallized tungsten layer (a W layer) 506. In the following, description will be mainly made of a film forming sequence (also referred simply as a sequence) used in forming a tungsten film (a W film) as a bulk layer.

Conducted in a suitable sequence of the present embodiment are a step of forming an amorphous metal film (e.g., a W film) on the wafer 200 by time-divisionally conducting steps a predetermined number of times, the step of forming a first amorphous metal layer (e.g., a W layer) on the wafer 200 by simultaneously supplying a metal-containing gas (e.g., WF₆ gas) and a first reducing gas (e.g., H₂ gas) to the wafer 200, and the step of forming a second amorphous metal layer (e.g. a W layer) on the first amorphous metal layer by time-divisionally (asynchronously, intermittently, pulsively) supplying the metal-containing gas and a second reducing gas (e.g., B₂H₆ gas) to the substrate on which the first amorphous metal film is formed a predetermined number of times; and a step of forming a crystallized metal layer (e.g., a W layer) on the amorphous metal film formed on the wafer 200 by simultaneously supplying the metal-containing gas and the first reducing gas to the wafer 200 on which the amorphous metal film is formed.

Specifically, as a sequence shown in FIG. 5, conducted is a step of forming an amorphous W film (also referred to as an amorphous W film, or an α-W film) on the wafer 200 by time-divisionally conducting, a predetermined number of times (n₂ times), a step of forming a first amorphous W layer (also referred to as an amorphous W layer, or an α-W layer) by simultaneously supplying a WF₆ gas and an H₂ gas and a step of forming a second α-W layer on a first α-W layer by time-divisionally supplying a WF₆ gas and a B₂H₆ gas a predetermined number of times (n₁ times), thereby forming a crystallized W layer on an α-W film by simultaneously supplying the WF₆ gas and the H₂ gas.

In the present specification, “conducting processing (or referred to as a step, a cycle, a step or the like) a predetermined number of times” denotes that the processing or the like is conducted once or a plurality of times. Specifically, it is denoted that the processing is conducted at least once. FIG. 5 shows an example in which each processing (cycle) is repeated in an n₁ cycle and an n₂ cycle alternately. A value of n₁ is appropriately selected according to a film thickness of the second α-W layer required for preventing crystallization of the first α-W layer to be formed next. A value of n₂ is appropriately selected according to a film thickness required of an α-W film to be finally formed.

In the present specification, “time-divisionally” denotes being separated in terms of time. In the present specification, for example, time-divisionally conducting each processing denotes conducting each processing asynchronously, i.e. without synchronization. In other words, it is denoted that each processing is conducted intermittently (pulsively) and alternately. That is, it is denoted that a processing gas supplied in each processing is supplied without being mixed with each other. When each processing is conducted a plurality of times, a processing gas supplied in each processing is alternately supplied without being mixed with each other.

In addition, the term “wafer” in the present specification may denote “a wafer itself” or may denote that “a laminate (aggregate) of a wafer and specific layer, film and the like formed on a surface thereof”, i.e., may be referred to as a wafer including specific layer, film and the like formed on a surface thereof. In addition, in the present specification, the term “a surface of a wafer” may denote “a surface (exposed surface) of a wafer itself” or may denote “a surface of specific layer, film and the like formed on a wafer, i.e., a topmost surface of a wafer as a laminate”.

Accordingly, in the present specification, recitation that “supply a specific gas to a wafer” may denote “directly supply a specific gas to a surface (exposed surface) of a wafer itself”, or “supply a specific gas to a layer, a film and the like formed on a water, i.e., to a topmost surface of a wafer as a laminate”. In addition, in the present specification, recitation that “form a specific layer (or film) on a wafer” may denote that “directly form a specific layer (or film) on a surface (exposed surface) of a wafer itself” or may denote that “form a specific layer (or film) on a layer, a film or the like formed on a wafer, i.e., form a specific layer (or film) on a topmost surface of a wafer as a laminate”.

The same is applied to use of the term “substrate” in the present specification as is applied to use of the term “wafer”, and in such a case, it is only necessary to replace “a wafer” in the above description with “a substrate”.

In addition, in the present specification, the term “metal film” represents a film formed of a conductive substance which contains metal atoms (also referred simply as a conductive film), the film including an elemental metal film mainly formed only of metal atoms, a conductive metal nitride film, a conductive metal oxide film, a conductive metal oxynitride film, a conductive metal oxycarbide film, a conductive metal composite film, a conductive metal alloy film, a conductive metal silicide film, a conductive metal carbide film, a conductive metal carbonitride film, and the like. Additionally, a W film is a conductive metal film and an elemental metal film.

In addition, in the present specification, the term “amorphous film (or layer)” denotes that a main component forming a corresponding film (layer) is yet to be crystallized, and the term “crystallized film (or layer)” denotes that a main component forming a corresponding film (layer) is crystallized (crystalline). Accordingly, “an amorphous film (or layer)” may include an amount of crystallized components to an extent that the components are not main components, and “crystallized film (or layer)” may include an amount of amorphous components to an extent that the components are not main components. In addition, “α” or “a” attached to a name of a kind of film, or the like represents being amorphous.

(Wafer Charge and Boat Load)

When the boat 217 is charged with a plurality of wafers 200 (wafer charge), as shown in FIG. 1, the boat 217 supporting the plurality of wafers 200 is lifted up by the boat elevator 115 and carried into the processing chamber 201 (boat load). In this state, the seal cap 219 blocks the lower end opening of the manifold 209 via the O-ring 220.

(Pressure Adjustment and Temperature Adjustment)

The processing chamber 201 is evacuated by the vacuum pump 246 so as to have a desired pressure (the degree of vacuum). On this occasion, the pressure in the processing chamber 201 is measured by the pressure sensor 245, and on the basis of information of this measured pressure, the APC valve 243 is feedback-controlled (pressure adjustment). The vacuum pump 246 maintains a state of constant operation until at least processing for the wafers 200 is completed. In addition, the wafers 200 in the processing chamber 201 are heated by the heater 207 so as to have a desired temperature. On this occasion, an amount of energization to the heater 207 is feedback-controlled on the basis of information of a temperature detected by the temperature sensor 263 such that the processing chamber 201 has a desired temperature distribution (temperature adjustment). In addition, heating in the processing chamber 201 by the heater 207 is continuously conducted until at least processing for the wafers 200 is completed. Subsequently, the rotation mechanism 267 causes the boat 217 and the wafers 200 to start rotation. In addition, the rotation of the boat 217 and the wafers 200 by the rotation mechanism 267 is continuously conducted until at least processing for the wafers 200 is completed.

(α-W Film Forming Step)

Subsequently, a step of forming an α-W film which forms a bulk layer is executed. The α-W film forming step includes a first α-W layer forming step of forming a first α-W layer as the α-W layer 504, which will be described in the following, and a second α-W layer forming step of forming a second α-W layer as the α-W layer 505.

(First α-W Layer Forming Step)

The step of forming a first α-W layer (an amorphous W layer) is executed. The first α-W layer forming step includes a WF₆ gas and H₂ gas supply step and a residual gas removal step which will be described in the following.

(WF₆ Gas and H₂ Gas Supply Step)

The valves 314 and 324 are opened to cause the WF₆ gas and the H₂ gas to flow into the gas supply pipes 310 and 320, respectively. With flow rates adjusted by the MFCs 312 and 322, respectively, the WF₆ gas having flowed in the gas supply pipe 310 and the H₂ gas having flowed in the gas supply pipe 320 are supplied into the processing chamber 201 from the gas supply holes 410a and 420a of the nozzles 410 and 420, respectively, and exhausted from the exhaust pipe 231. At this time, the WF₆ gas and the H₂ gas are to be supplied to the wafer 200. In other words, the surface of the wafer 200 will be exposed to the WF₆ gas and the H₂ gas. At this time, the valves 514 and 524 are simultaneously opened to cause the N₂ gas to flow into the carrier gas supply pipes 510 and 520, respectively. With flow rates adjusted by the MFCs 512 and 522, respectively, the N₂ gas having flowed in the carrier gas supply pipes 510 and 520 are supplied into the processing chamber 201 together with the WF₆ gas or the H₂ gas and exhausted from the exhaust pipe 231. At this time, for preventing the WF₆ gas and the H₂ gas from entering the nozzle 430, the valve 534 is opened to cause the N₂ gas flow into the carrier gas supply pipe 530. The N₂ gas is supplied into the processing chamber 201 via the gas supply pipe 330 and the nozzle 430 and exhausted from the exhaust pipe 231.

At this time, the APC valve 243 is appropriately adjusted to set a pressure in the processing chamber 201 to be a pressure within a range of, for example, 10 to 1300 Pa, to be 70 Pa, for example. A supply flow rate of a WF₆ gas controlled by the MFC 312 is set to be a flow rate within a range of, for example, 10 to 1000 sccm, to be 100 sccm, for example, and a supply flow rate of an H₂ gas controlled by the MFC 322 is set to be a flow rate within a range of, for example, 100 to 20000 sccm, to be 10000 sccm, for example. A supply flow rate of a N₂ gas controlled by each of the MFCs 512, 522, and 532 is set to be a flow rate within a range of, for example, 10 to 10000 sccm, to be 5000 sccm, for example. Time for supplying a WF₆ gas and an H₂ gas to the wafer 200, i.e. a gas supply time (irradiation time), is set to be time within a range of, for example, 1 to 1000 seconds. At this time, a temperature of the heater 207 is set such that a temperature of the wafer 200 is a temperature within a range of a room temperature to 250° C., and preferably a temperature within a range of 150 to 230° C., for example, 200° C. In addition, when the temperature of the wafer 200 is lower than a room temperature, reaction energy falls short of film formation, so that film forming is highly probably inhibited. In addition, when the temperature of the wafer 200 is 250° C. or higher, a B₂H₆ gas to be supplied at a B₂H₆ gas supply step in the second α-W layer forming step self-decomposes to deposit B, highly probably inhibiting film forming.

The WF₆ gas and the H₂ gas flowing in the processing chamber 201 react in a gas phase (gas phase reaction) or react on a substrate surface to form a first α-W layer on the wafer 200 (a base film of the surface, e.g., the seed layer 503). Here, an α-W layer represents, other than a continuous layer formed of amorphous W, an incontinuous layer, or an amorphous W layer obtained by a lamination of these layers, and the α-W layer may include F contained in a WF₆ molecule in some cases. By controlling (adjustment, control) process conditions such as supply flow rates and supply time of the WF₆ gas and H₂ gas, or the like, an α-W layer can be grown up to a desired film thickness.

In a case of a gas phase reaction, crystallization of a film depends on a thickness of the film. Therefore, at the first α-W layer forming step, before the W film has a film thickness at which crystallization occurs, supply of the WF₆ gas and the H₂ gas is stopped. In a case of a W film, for example, a film thickness at which no crystallization occurs is desirably more than 0 nm and 3 nm or less. Preferably, the film thickness is set to be 0.1 nm or more and 3 nm or less.

(Residual Gas Removal Step)

After a first α-W layer with a specific film thickness is formed, the valves 314 and 324 are closed to stop supply of the WF₆ gas and the H₂ gas. At this time, with the APC valve 243 remaining open, the vacuum pump 246 evacuates the processing chamber 201 to remove, from the processing chamber 201 (i.e. a space where the wafer 200 on which the first α-W layer is formed is present), the WF₆gas and the H₂ gas unreacted or after contributing to formation of the first α-W layer, the gases remaining in the processing chamber 201. At this time, with the valves 514, 524, and 534 remaining open, supply of the N₂ gas into the processing chamber 201 is maintained. The N₂ gas functions as a purge gas to be able to increase an effect of removing, from the processing chamber 201, the WF₆ gas and the H₂ gas unreacted or after contributing to formation of the first α-W layer, the gases remaining in the processing chamber 201. At this time, when a by-product has been generated in the processing chamber 201 by the first α-W layer forming step, the by-product is also removed from the processing chamber 201.

At this time, a residual gas in the processing chamber 201 may not necessarily be removed completely, and the processing chamber 201 may not necessarily be purged completely. To an extent that causes no adverse effect at steps to be conducted thereafter, a small amount of gas is allowed to remain in the processing chamber 201. In addition, it is not necessary to set a flow rate of the N₂ gas to be supplied into the processing chamber 201 to a high flow rate, and for example, supplying a N₂ gas of a volume approximately the same as a capacity of the reaction tube 203 (the processing chamber 201) enables purging to an extent not to cause an adverse effect in the following steps. Thus, by not completely purging the processing chamber 201, a purge time can be reduced to improve a throughput. In addition, consumption of a N₂ gas can be suppressed to be a minimum volume as required.

(Second α-W Layer Forming Step)

Subsequently, the step of forming a second α-W layer is executed. The second α-W layer forming step includes a WF₆ gas supply step, a residual gas removal step, a B₂H₆ gas supply step, and a residual gas supply step, which will be described in the following.

(WF₆ Gas Supply Step)

The valve 314 is opened to cause the WF₆ gas to flow in the gas supply pipe 310. With a flow rate adjusted by the MFC 312, the WF₆ gas flowing in the gas supply pipe 310 is supplied from the gas supply hole 410a of the nozzle 410 into the processing chamber 201 and exhausted from the exhaust pipe 231. At this time, to the wafer 200, a WF₆ gas is to be supplied. In other words, the surface of the wafer 200 will be exposed to the WF₆ gas. At this time, the valve 514 is simultaneously opened to cause the N₂ gas to flow into the carrier gas supply pipe 510. With a flow rate adjusted by the MFC 512, the N₂ gas flowing in the carrier gas supply pipe 510 is supplied into the processing chamber 201 together with the WF₆ gas and exhausted from the exhaust pipe 231. At this time, in order to prevent the WF₆ gas from entering the nozzles 420 and 430, the valves 524 and 534 are opened to cause the N₂ gas to flow into the carrier gas supply pipes 520 and 530. The N₂ gas is supplied into the processing chamber 201 via the gas supply pipes 320 and 330, and the nozzles 420 and 430 and exhausted from the exhaust pipe 231.

At this time, the APC valve 243 is appropriately adjusted to set the pressure in the processing chamber 201 to be a pressure within a range of, for example, 10 to 1300 Pa, and set to be 70 Pa, for example. The supply flow rate of the WF₆ gas controlled by the MFC 312 is set to be a flow rate within a range of, for example, 10 to 1000 sccm, to be 100 sccm, for example. The supply flow rates of the N₂ gas controlled by each of the MFCs 512, 522, and 532 is set to be a flow rate within a range of, for example, 10 to 10000 sccm, to be 5000 sccm, for example. Time for supplying a WF₆ gas to the wafer 200, i.e. a gas supply time (irradiation time), is set to be time within a range of, for example, 0.1 to 50 seconds. At this time, a temperature of the heater 207 is to the same temperature as in the first α-W layer forming step. The gases flowing in the processing chamber 201 are the WF₆ gas and the N₂ gas only, and the supply of the WF₆ gas forms an α-W-containing layer with a thickness, for example, on the order from less than one atomic layer to several atomic layers on the first α-W layer formed on the wafer 200.

The α-W-containing layer is ideally an α-W layer but may include an α-W (F) layer as a main element in some cases. In addition, the α-W layer includes, other than a continuous layer formed of α-W, an incontinuous layer. Specifically, the α-W layer includes a W-deposited layer formed of α-W and having a thickness on the order from less than one atomic layer to several atomic layers. The α-W (F) layer is a W-containing layer including F and may be an α-W layer including F or may be a WF₆ adsorption layer. In addition, when the α-W (F) layer a main element, in particular, reduction reaction by the B₂H₆ gas supply step which will be described later is effective.

A W layer including F is a generic name including, other than a continuous layer formed of W and containing F, an incontinuous layer and a W thin film formed of a lamination of these layers and containing F. A continuous layer formed of W and containing F may be called a W thin film containing F in some cases. W forming a W layer containing F includes, other than W with coupling thereof with F not completely broken, W with coupling thereof with F completely broken.

The WF₆ adsorption layer includes, other than a continuous adsorption layer formed of WF₆ molecules, an incontinuous adsorption layer. Specifically, the WF₆ adsorption layer includes an adsorption layer formed of WF₆ molecules and having a thickness of one molecular layer or less than one molecular layer. The WF₆ molecules forming the WF₆ adsorption layer include molecules with a coupling between W and F partly broken. Specifically, the WF₆ adsorption layer may be a WF₆ physical adsorption layer or a WF₆ chemical adsorption layer, or may include both of the layers.

Here, “a layer with a thickness of less than one atomic layer” represents an incontinuously formed atomic layer, and “a layer with a thickness of one atomic layer” represents a continuously formed atomic layer. “A layer with a thickness of less than one molecular layer” represents an incontinuously formed molecular layer, and “a layer with a thickness of one molecular layer” represents a continuously formed molecular layer. The α-W-containing layer can include both a W layer containing F and a WF₆ adsorption layer. However, as described above, an α-W-containing layer will be represented as such expression as “one atomic layer”, “several atomic layers” or the like.

Under a condition where the WF₆ gas autolyzes (thermal decomposition), i.e., under a condition where thermal decomposition reaction of the WF₆ occurs, a W layer containing F is formed on the wafer 200 as result of deposition of W. Under a condition where the WF₆ gas does not autolyze (thermal decomposition), i.e., under a condition where no thermal decomposition reaction of the WF₆ gas occurs, an adsorption layer of WF₆ is formed on the wafer 200 as a result of adsorption of WF₆. Forming a W layer containing F on the wafer 200 is more preferable than forming an adsorption layer of WF₆ on the wafer 200 in terms of an increase in a film forming rate.

When a thickness of the W-containing layer exceeds several atomic lavers, a function of reduction at a B₂H₆ gas supply step which will be described later does not act on the entire α-W-containing layer. In addition, a minimum thickness of the α-W-containing layer is less than one atomic layer. Therefore, the thickness of the first layer is preferably from less than one atomic layer to several atomic layers. Setting the thickness of the α-W-containing layer to be one atomic layer or less, i.e. one atomic layer or less than one atomic layer, enables a function of reduction reaction to be relatively enhanced at the B₂H₆ gas supply step which will be described later, thereby enabling reduction in time required for reduction reaction at the B₂H₆ gas supply step. Time required for forming the α-W-containing layer at the WF₆ gas supply step can be also reduced. As a result, processing time per one cycle can be reduced to reduce a total processing time as well. In other words, a film forming rate can be increased as well. In addition, by setting the thickness of the α-W-containing layer to be one atomic layer or less, controllability of uniformity in a film thickness can be also enhanced.

(Residual Gas Removal Step)

After an α-W-containing layer with a specific film thickness is formed, the valves 314 and 324 are closed to stop supply of the WF₆ gas. At this time, with the APC valve 243 remaining open, the processing chamber 201 is evacuated by the vacuum pump 246 to remove, from the processing chamber 201, a WF₆ gas unreacted or after contributing to formation of the α-W-containing laver, the gas remaining in the processing chamber 201. Specifically, a WF₆ gas which is unreacted or has contributed to formation of the α-W-containing layer is removed, the gas remaining in a space where the wafer 200 on which the α-W-containing layer is formed is present. At this time, with the valves 514, 524, and 534 remaining open, supply of the N₂ gas into the processing chamber 201 is maintained. The N₂ gas functions as a purge gas to enhance an effect of removing, from the processing chamber 201, the WF₆ gas which is unreacted or has contributed to formation of the α-W-containing layer, the WF₆ gas remaining in the processing chamber 201.

At this time, similarly to the residual gas removal step after the WF₆ gas supply step, a residual gas in the processing chamber 201 may not necessarily be removed completely, and the processing chamber 201 may not necessarily be purged completely.

(B₂H₆ Gas Supply Step)

The valve 334 is opened to cause a B₂H₆ gas to flow into the gas supply pipe 330. With a flow rate adjusted by the MFC 332, the B₂H₆ gas flowing in the gas supply pipe 330 is supplied from the gas supply hole 430a of the nozzle 430 into the processing chamber 201 and exhausted from the exhaust pipe 231. At this time, the B₂H₆ gas is to be supplied to the wafer 200. In other words, the surface of the wafer 200 will be exposed to the B₂H₆ gas. At this time, the valve 534 is simultaneously opened to cause the N₂ gas to flow into the carrier gas supply pipe 530. With the flow rate adjusted by the MFC 532, the N₂ gas flowing in the carrier gas supply pipe 530 is supplied into the processing chamber 201 together with the B₂H₆ gas and exhausted from the exhaust pipe 231. At this time, in order to prevent the B₂H₆ gas from entering the nozzles 410 and 420, the valves 514 and 524 are opened to cause the N₂ gas to flow into the carrier gas supply pipes 510 and 520. The N₂ gas is supplied into the processing chamber 201 via the gas supply pipes 310 and 320, and the nozzles 410 and 420, and exhausted from the exhaust pipe 231.

At this time, the APC valve 243 is appropriately adjusted to set a pressure in the processing chamber 201 to be a pressure within a range of, for example, 10 to 1300 Pa, to be 70 Pa, for example. A supply flow rate of the B₂H₆ gas controlled by the MFC 332 is set to be a flow rate within a range of, for example, 10 to 20000 sccm, to be 10000 sccm, for example. The supply flow rates of the N₂ gases controlled by the MFCs 512, 522, and 532 are each within a range of, for example, 10 to 10000 sccm, to be 5000 sccm, for example. Time for supplying the B₂H₆ gas to the wafer 200, i.e. a gas supply time (irradiation time) is set to be time within a range of, for example, 0.1 to 60 seconds. At this time, a temperature of the heater 207 is set to be the same temperature as in the first α-W layer forming step and the WF₆ gas supply step. The gases flowing in the processing chamber 201 are the B₂H₆ gas and the N₂ gas only, and supply of the B₂H₆ gas reduces the α-W-containing layer formed on the wafer 200 at the WF₆ gas supply step to form a second α-W layer. Specifically, H of the B₂H₆ gas reacts with F contained in the α-W-containing layer formed at the WF₆ gas supply step to be reduced as hydrogen fluoride (HF). At this time, at least a part of boron (B), which is a residual component of the B₂H₆ gas, might remain in the second α-W layer as a residue. Accordingly, at least a part of the second α-W layer might be an α-W (B) layer, i.e. an α-W layer containing B in some cases. It can be considered that B thus remaining as impurities in the α-W layer brings the formed α-W (B) layer into an amorphous state. Accordingly, in this respect, B remaining as impurities in the α-W layer is preferable.

(Residual Gas Removal Step)

Subsequently, by the same processing as that of the residual gas removal step after the WF₆ gas supply step, a B₂H₆ gas unreacted or after contributing to formation of the second α-W layer, and a by-product are removed from the processing chamber 201, the gas and the by-product remaining in the processing chamber 201. In other words, the B₂H₆ gas unreacted or after contributing to formation of the second α-W layer, and a by-product are removed, the B₂H₆ gas and the by-product remaining in a space where the wafer 200 on which the second α-W layer is formed is present.

(Specific Number of Times of Execution)

By executing, at least once (a predetermined number of times), a cycle in which the above WF₆ gas supply step, residual gas removal step, B₂H₆ gas supply step, and residual gas removal step are sequentially conducted in a time-divisional manner (asynchronously, intermittently, pulsively), i.e., with the WF₆ gas supply step, the residual gas removal step, the B₂H₆ gas supply step, and the residual gas removal step as one cycle, by executing n₁ cycle (n₁ is an integer of one or more) of these processings, a second α-W layer with a specific thickness (e.g. 0.1 to 2.0 nm) is formed on the wafer 200. The specific thickness is determined in consideration of a film thickness required for allowing a W layer to be formed as an amorphous W layer (first α-W layer), without crystallization, the W layer to be formed on the second α-W layer when the first α-W layer forming step is executed next. The above steps are preferably repeated a plurality of times. In addition, at the second α-W film forming step, the WF₆ gas supply step and the B₂H₆ gas supply step may be executed in reverse order. Specifically, the respective steps may be executed in the order of the B₂H₆ gas supply step, the residual gas removal step, the WF₆ gas supply step, and the residual gas removal step.

(Specific Number of Times of Execution)

By time-divisionally executing the above-described first α-W layer forming step and second α-W layer forming step n₂ (n₂ is an integer of one or more) times, an α-W film with a specific thickness is formed on the wafer 200, which film is formed as a laminate film (nano-laminate film) with the first α-W layers and the second α-W layers alternately laminated on a nano-level. The above-described step is preferably repeated a plurality of times.

(Crystallized W Layer Forming Step)

Subsequently, a step of forming a W layer which is crystallized (crystallized W layer) is executed. The crystallized W layer forming step includes the same steps as the WF₆ gas and H₂ gas supply step and the residual gas removal step in the first α-W layer forming step of the α-W layer forming step. In the following, only a part different from the first α-W layer forming step will be described.

(WF₆ Gas and H₂ Gas Supply Step)

The present step is changed from the WF₆ gas and H₂ gas supply step in the first α-W layer forming step in at least one of a supply flow rate and a supply time of the WF₆ gas and the H₂ gas. Specifically, a WF₆ gas supply flow rate controlled by the MFC 312 is a flow rate within a range of, for example, 10 to 1000 sccm, to be 100 sccm, for example, and an H₂ gas supply flow rate controlled by the MFC 322 is a flow rate within a range of, for example, 10 to 20000 sccm, to be 10000 sccm, for example. A N₂ gas supply flow rate controlled by each of the MFCs 512, 522, and 532 is a flow rate within a range of, for example, 10 to 10000 sccm, to be 5000 sccm, for example. Time for suppling the WF₆ gas and the H₂ gas to the wafer 200, i.e., a gas supply time (irradiation time) is set to be time within a range of, for example, 0.1 to 1000 seconds. Thus, a crystallized W layer is formed on an α-W film formed on the wafer 200.

As described above, in a case of a gas phase reaction, crystallization of a film depends on a thickness of the film. Therefore, by changing at least one of a supply flow rate and a supply time of the WF₆ gas and the H₂ gas from that of the first α-W layer forming step, a crystallized W layer is formed. The crystallized W layer is a film thicker than 3 nm and is formed to have a film thickness required for crystallization of the α-W film due to (reversed) solid phase reaction. With such a film thickness, it can be considered that a crystallized W layer affects an α-W layer at a lower part to gradually crystallize the α-W layer. At this time, it can be also considered that only the upper layer portion of the α-W layer is affected by the crystallized W layer and is crystallized, or substantially all the α-W layers are crystallized. It can be considered that a range of a region affected by crystallization is determined on the basis of a film thickness of a crystallized W layer formed.

(Residual Gas Removal Step)

After the crystallized W layer with a specific film thickness is formed, the valves 314 and 324 are closed to stop supply of the WF₆ gas and the H₂ gas. At this time, with the APC valve 243 remaining open, the processing chamber 201 is evacuated by the vacuum pump 246, and the WF₆ gas and the H₂ gas which are unreacted or have contributed to formation of the crystallized W layer are removed from the processing chamber 201, the WF₆ gas and the H₂ gas remaining in the processing chamber 201. In other words, the WF₆ gas and the H₂ gas unreacted or after contributing to formation of the crystallized W layer are removed, the gases remaining in a space where the wafer 200 on which the crystallized W layer is formed is present. At this time, with the valves 514, 524, and 534 remaining open, supply of the N₂ gas into the processing chamber 201 is maintained. The N₂ gas functions as a purge gas to enhance an effect of removing, from the processing chamber 201, the WF₆ gas and the H₂ gas which are unreacted or have contributed to formation of the crystallized W layer and remain in the processing chamber 201.

(Purge and Return to Atmospheric Pressure)

After the crystallized W layer with a specific film thickness is formed on the wafer 200, with the valves 514, 524, and 534 remaining open, the N₂ gas is supplied into the processing chamber 201 from the gas supply pipes 510, 520, and 530, respectively, and exhausted from the exhaust pipe 231. The N₂ gas functions as a purge gas, thereby purging the processing chamber 201 with an inert gas to remove (purge), from the processing chamber 201, a gas and a by-product remaining in the processing chamber 201. Thereafter, an atmosphere in the processing chamber 201 is substituted with an inert gas (inert gas substitute) to return the pressure in the processing chamber 201 to a normal pressure (return to the atmospheric pressure).

(Boat Unload and Wafer Discharge)

The seal cap 219 is lowered by the boat elevator 115 to open a lower end of the manifold 209. Then, being supported by the boat 217, the wafer 200 subjected to processing is carried out from the lower end of the manifold 209 to the outside the processing chamber 201 (boat unloaded). The wafer 200 subjected to the processing is taken out from the boat 217 (wafer discharged).

(3) Effect Obtained by the Present Embodiment

The present embodiment obtains one or a plurality of effects shown below.

In the present embodiment, based on that when a plurality of processing gases are simultaneously supplied to a substrate to form a film, to a certain fixed film thickness, the film is grown in an amorphous state (a first α-W layer as an amorphous W film (A)), and over the certain fixed film thickness, the film is crystallized, and that at the time of time-divisionally supplying a plurality of processing gases to the substrate to form a layer, impurities remain to bring the formed layer into an amorphous state (a second α-W layer as an amorphous W film (B)), by forming an α-W film as an amorphous W film having a desired film thickness by combining the first α-W layer and the second α-W layer, an α-W film can be formed by low temperature processing at 250° C. or less and preferably 200° C. or less. Furthermore, the α-W film forming step and the crystallized W layer forming step are conducted in the same processing chamber.

Further, forming a W layer on an α-W film, the layer being obtained by crystallizing a film formed with a certain fixed film thickness or larger by simultaneously supplying a plurality of processing gases to a substrate enables an effect of crystallization to be applied to at least a part of the α-W film, so that by low temperature processing at 250° C. or less and preferably 200° C. or less, a crystallized W film with low roughness and a low resistivity can be formed in an extra fine groove with a narrow opening so as to have an excellent embedding property.

### Second Embodiment of the Present Invention

In the first embodiment, the description has been made of an example in which as a bulk layer, an α-W film is formed by combining a first α-W layer and a second α-W layer, on which film, a crystallized W layer is formed, thereby forming a crystallized W film with a desired film thickness by low temperature processing at 250° C. or less and preferably 200° C. or less. In the present embodiment, description will be made, with reference to FIG. 6, of an example where as a base of the above-described bulk layer, the tungsten film (W film) 503 is formed as a seed layer formed on the TiN film 502 formed as a barrier metal film. No detailed description will be made of the same part as the first embodiment, and a part different from the first embodiment will be described in the following.

(Seed W Film Forming Step)

A W film as a seed layer (a seed W film) is formed by executing a seed W film forming step including a WF₆ gas supply step, a residual gas removal step, a B₂H₆ gas supply step, and a residual gas supply step, similarly to the second α-W layer forming step described in the first embodiment. A process condition in each step is the same as that of the second α-W layer forming step and therefore no description will be made thereof.

By executing, at least once (a predetermined number of times), a cycle in which the WF₆ gas supply step, the residual gas removal step, the B₂H₆ gas supply step, and the residual gas removal step are sequentially conducted in a time-divisional manner (asynchronously, intermittently, pulsively), i.e., with the WF₆ gas supply step, the residual gas removal step, the B₂H₆ gas supply step, and the residual gas removal step as one cycle, by executing n₃ cycle (n₃ is an integer of one or more) of these processings, a seed W film with a specific thickness (e.g. 0.1 to 3 nm) is formed on the wafer 200. In addition, similarly to the second α-W film forming step, the WF₆ gas supply step and the B₂H₆ gas supply step may be executed in reverse order. Specifically, the respective steps may be executed in the order of the B₂H₆ gas supply step, the residual gas removal step, the WF₆ gas supply step, and the residual gas removal step. In this case, since a gas which first comes into contact with the TiN film 502 formed as a barrier metal film is a B₂H₆ gas, damages to the TiN film can be mitigated more as compared with a case where the WF₆ gas comes first in contact with the film.

(1) Effect Obtained by the Present Embodiment

The present embodiment obtains one or a plurality of effects shown below.

In the present embodiment, forming a seed layer enables a flat bulk film to be formed on an entire surface of the wafer 200, as well as enabling a resistance of the bulk layer to be reduced. In addition, time-divisionally supplying a plurality of processing gases to form a film suppresses crystallization, thereby enabling formation of a further flat tungsten film.

### Other Embodiment

The present invention is not limited to the above-described embodiment, and various modifications are allowed within a range not departing from a gist thereof.

In the above embodiment, the description has been made of an example where a W film is formed as an amorphous film and as a crystallized film. The present invention is not limited to the above aspect but is effective for forming a film having such properties that when in a low temperature region with a room temperature or more and 250° C. or less (preferably 200° C. or less), a plurality of processing gases are simultaneously supplied to form a film, crystallization occurs with a certain fixed film thickness or larger, and when a plurality of gases are time-divisionally supplied to form a film, no crystallization occurs (as amorphous). The present invention is also suitably applicable when forming, for example, a metal nitride film (metal nitride) or a metal carbide film (metal carbide) containing such metallic elements as W, titanium (Ti), tantalum (Ta), molybdenum (Mo), zinc (Zn) and the like, a metal film of copper (Cu), ruthenium (Ru), aluminum (Al) or the like, and a film as a combination thereof.

Examples of applicable metal nitride film and metal carbide film include metal nitride-based films and metal carbide-based film such as a WN film, a TiN film, a TaN film, a MoN film, a ZnN film, a WC film, a TiC film, a TaC film, a MoC film, a ZnC film, a WCN film, a TiCN film, a TaCN film, a MoCN film, a ZnCN film and the like, metal films such as a Cu film, a Ru film, an Al film and the like, and a film as a combination thereof.

In addition, when forming the above-described metal nitride film or metal carbide film, also usable other than WF₆ are tungsten hexachloride (WCl₆), titanium tetrachloride (TiF₄), titanium tetrachloride (TiCl₄), tantalum pentafluoride (TaF₅), tantalum pentachloride (TaCl₅), molybdenum pentafluoride (MoF₅), molybdenum pentachloride (MoCl₅), zinc dichloride (ZnCl₂), zinc difluoride (ZnF₂) and the like.

Although in the above-described embodiment, the description has been made of an example where a B₂H₆ gas is used as a B-containing gas as a reducing gas, in place of a B-containing gas, a mono-silane (SiH₄) gas, a disilane (Si₂H₆) gas and the like can be also used as a silicon-containing gas (silane-based gas).

As an H-containing gas as a reducing gas, other than an H₂ gas, a heavy hydrogen (D₂) gas which is an H-containing gas including no other element, and the like can be also used.

As an inert gas, other than N₂ gas, rare gases such as an argon (Ar) gas, a helium (He) gas, a neon (Ne) gas, a xenon (Xe) gas and the like may be used.

The above-described embodiments, the respective modifications, applications and the like can be used inappropriate combination. In addition, a processing condition in this case can be the same, for example, as the above processing condition of the embodiments.

It is preferable to prepare a process recipe for use in forming these various thin films (a program in which a processing procedure, a processing condition, and the like are recited) individually (prepared in plural) according to contents of substrate processing (a kind of thin film to be formed, a composition ratio, a film quality, a film thickness, a processing procedure, a processing condition and the like). Then, at the start of substrate processing, it is preferable to appropriately select an appropriate process recipe from a plurality of process recipes according to contents of the substrate processing. Specifically, it is preferable to in advance store (install) a plurality of process recipes individually prepared according to the contents of the substrate processing in the storage device 121c provided in the substrate processing apparatus via an electric communication line or a recording medium (the external storage device 123) which records the process recipe in question. Then, at the start of the substrate processing, it is preferable that the CPU 121a provided in the substrate processing apparatus appropriately selects an appropriate process recipe from a plurality of process recipes stored in the storage device 121c according to contents of the substrate processing. Such a configuration allows one substrate processing apparatus to versatilely form, with excellent reproducibility, thin films of various kinds, composition ratios, film qualities, and film thicknesses. In addition, an operation load of an operator (a load of inputting a processing procedure, a processing condition, and the like) can be reduced to quickly start the substrate processing while avoiding an operation error.

The above-described process recipe can be realized by, not limited to newly generating, changing, for example, a process recipe of an existing substrate processing apparatus. In a case of changing a process recipe, also by installing a process recipe according to the present invention in an existing substrate processing apparatus via an electric communication line or a recording medium which records the process recipe in question, or operating an input/output device of an existing substrate processing apparatus, the process recipe itself can be changed to the process recipe according to the present invention.

Although in the above-described embodiment, the description has been made of an example of forming a film using a processing furnace, which is a substrate processing apparatus as a batch-type vertical apparatus that processes a plurality of substrates at once, and has a structure in which a nozzle for supplying a processing gas is erected in one reaction tube and at a bottom portion of the reaction tube, an exhaust port is provided, the present invention is also applicable to film-forming using a processing furnace having other structure. The present invention is also applicable to film-forming using, for example, a processing furnace having a structure in which two reaction tubes each having a concentrical section (an outer reaction tube will be referred to as an outer tube, and an inner reaction tube will be referred to as an inner tube) are provided so that from a nozzle erected in the inner tube, a processing gas flows to an exhaust port opened at a position on a side wall of the outer tube and opposed to the nozzle with a substrate provided therebetween (line symmetrical position). In addition, the processing gas may not be supplied from the nozzle erected in the inner tube, but may be supplied from a gas supply port opened on the side wall of the inner tube. At this time, the exhaust port opened in the outer tube can be opened according to a height of a plurality of substrates which is housed in lamination in a processing chamber. In addition, the exhaust port may have a hole-shape or a slit-shape.

While in the above-described embodiment, the description has been made of an example of forming a film using a substrate processing apparatus as a batch-type vertical apparatus that processes a plurality of substrates at once, the present invention is not limited thereto, but is suitably applicable to a case of forming a film using a sheet-type substrate processing apparatus which processes one or a few substrates at once. In addition, although the above embodiment has been described with respect to an example of forming a thin film using a substrate processing apparatus having a hot-wall type processing furnace, the present invention is not limited thereto, but is also suitably applicable to a case of forming a thin film using a substrate processing apparatus having a cold-wall type processing furnace. Also in these cases, a processing condition can be the same as, for example, the above-described processing condition of the embodiments.

### INDUSTRIAL APPLICABILITY

A technique is provided that enables formation of a high-quality film with reduced roughness and a low resistivity.

### REFERENCE SIGNS LIST

10 substrate processing apparatus
200 wafer
201 processing chamber
202 processing furnace

1. A method of manufacturing a semiconductor device comprising:
forming an amorphous metal film on a substrate by time-divisionally conducting a cycle a predetermined number of times, the cycle comprising:
(a) simultaneously supplying a metal-containing gas and a first reducing gas to the substrate to form a first amorphous metal layer on the substrate, and
(b) forming a second amorphous metal layer on the first amorphous metal layer by time-divisionally supplying, a predetermined number of times, the metal-containing gas and a second reducing gas to the substrate on which the first amorphous metal layer is formed; and
forming a crystallized metal layer on the substrate by simultaneously supplying the metal-containing gas and the first reducing gas to the substrate on which the amorphous metal film is formed.

2. The method of manufacturing a semiconductor device according to claim 1, wherein the forming of a first amorphous metal layer, the forming of a second amorphous metal layer, and the forming of a crystallized metal layer are each conducted in a state where the substrate is heated at a same predetermined temperature.

3. The method of manufacturing a semiconductor device according to claim 2, wherein the predetermined temperature is a temperature within a range of a room temperature or more and 200° C. or less.

4. The method of manufacturing a semiconductor device according to claim 1, wherein the second reducing gas is a boron-containing gas or a silicon-containing gas.

5. The method of manufacturing a semiconductor device according to claim 4, wherein the first reducing gas is hydrogen (H₂), and the second reducing gas is any one of diborane (B₂H₆), a mono-silane (SiH₄) gas and a disilane (Si₂H₆) gas.

6. The method of manufacturing a semiconductor device according to claim. 1, wherein the metal-containing gas is a tungsten-containing gas, the first amorphous metal layer and the second amorphous metal layer are amorphous tungsten layers, the amorphous metal film is an amorphous tungsten film, and the crystallized metal layer is a crystallized tungsten film.

7. The method of manufacturing a semiconductor device according to claim 1, wherein at the forming of a crystallized metal layer, at least a part of the amorphous metal film is crystallized by forming the crystallized metal layer on the amorphous metal film.

8. The method of manufacturing a semiconductor device according to claim 1, wherein at the forming of an amorphous metal film, the amorphous metal film is formed on a seed layer formed on a barrier metal film by the procedure (b).

9. The method of manufacturing a semiconductor device according to claim 8, wherein the barrier metal film is a titanium nitride film.

10. The method of manufacturing a semiconductor device according to claim 1, wherein the forming of the amorphous metal film and the forming of the crystallized metal layer are conducted in a same processing chamber.
